(19) United States
(12) Patent Application Publication
(10) Pub. No.: US 2024/0387481 A1
(43) Pub. Date: Nov. 21, 2024

(54) REPAIR METHODS FOR MICRO-LED DISPLAYS USING INTENSITY AVERAGING

(71) Applicant: Applied Materials, Inc., Santa Clara, CA (US)

(72) Inventors: Joseph R. JOHNSON, Redwood City, CA (US); Christopher BENCHER, Santa Clara, CA (US)

(21) Appl. No.: 18/667,090

(22) Filed: May 17, 2024

Related U.S. Application Data
(60) Provisional application No. 63/503,113, filed on May 18, 2023.

(51) Int. Cl. H01L 25/075; H01L 33/00; H01L 33/50

(52) U.S. Cl. CPC H01L 25/0753; H01L 33/0095; H01L 33/502; H01L 33/507

(57) ABSTRACT

Embodiments of the present disclosure relates to LED pixels and methods of fabricating LED pixels. The device includes a backplane, the backplane including a plurality of backplane electrodes, one or more LEDs, each LED having at least one LED electrode coupled a respective backplane electrode of the plurality of backplane electrode, at least two pixels, each pixel including sub-pixel isolation (SI) structures disposed over the LEDs, the SI structures defining wells of sub-pixels of each pixel, where a respective pixel includes three operational sub-pixels, each operational sub-pixel having an operational LED and a color conversion material disposed in each well, a defective LED sub-pixel, the defective LED sub-pixel having a defective LED, and where one of the at least two pixels has two operational sub-pixels having a same color conversion material disposed in each well.

This application claims benefit of and priority to U.S. Provisional Patent Application No. 63/503,113 filed May 18, 2023.

### BACKGROUND

### Field

Embodiments of the present disclosure generally relate to LED displays and methods of fabricating LED displays. Specifically, embodiments described herein provide methods and devices for repairing LED displays.

### Description of the Related Art

A light emitting diode (LED) panel uses an array of LEDs, with individual LEDs providing the individually controllable pixel elements. Such an LED panel can be used for a computer, touch panel device, personal digital assistant (PDA), cell phone, television monitor, and the like.

Light emitting diode (LED) technology is broadly implemented for display technology. Generally, implementations of LED technology utilize an LED panel with an array of LEDs. Individual LEDs within the array may provide individually controllable pixel elements, which may allow a user to display customizable images on the LED panel. Accordingly, in one example, LED technology may be a suitable display mechanism for end-user display devices, including a computer monitor, a touch panel device, a personal digital assistant (PDA), a cell phone, a television monitor, and the like. Current LED technology has provided an LED panel system that uses micron-scale LEDs based on III-V semiconductor technology (also called LEDs). LEDs offer a variety of advantages as compared to organic light emitting diodes (OLEDs) For example, LEDs facilitate higher energy efficiency, more robust display brightness, and longer display lifetimes. Manufacturers may also produce LEDs using fewer material layers in a display stack as compared to OLEDs, which may reduce the complexity and cost associated with LED production.

An alternative approach to bypass the pick-and-place step is to selectively deposit color conversion agents (e.g., quantum dots, nanostructures, photoluminescent materials, or organic substances) at specific pixel locations on a substrate fabricated with monochrome LEDs. The monochrome LEDs can generate relatively short wavelength light, e.g., purple or blue light, and the color conversion agents can convert this short wavelength light into longer wavelength light, e.g., red or green light for red or green pixels. The selective deposition of the color conversion agents can be performed using high-resolution shadow masks or controllable inkjet or aerosol jet printing.

However, challenges to fabrication of LED panels remain. Accordingly, there is a need in the art for improved LED displays and methods of fabricating LED displays.

### SUMMARY

In one embodiment, a device is provided. The device includes a backplane, the backplane including a plurality of backplane electrodes, one or more LEDs, each LED having at least one LED electrode coupled a respective backplane electrode of the plurality of backplane electrode, at least two pixels, each pixel including sub-pixel isolation (SI) structures disposed over the LEDs, the SI structures defining wells of sub-pixels of each pixel, where a respective pixel includes three operational sub-pixels, each operational sub-pixel having an operational LED and a color conversion material disposed in each well, a defective LED sub-pixel, the defective LED sub-pixel having a defective LED, and where one of the at least two pixels has two operational sub-pixels having a same color conversion material disposed in each well.

In another embodiment, a device is provided. The device includes a backplane, the backplane including a plurality of backplane electrodes, one or more LEDs, each LED having at least one LED electrode coupled a respective backplane electrode of the plurality of backplane electrode, at least two pixels, each pixel including sub-pixel isolation (SI) structures disposed over the LEDs, the SI structures defining wells of sub-pixels of each pixel, where a respective pixel includes, three operational sub-pixels, each operational sub-pixel having an operational LED and a color conversion material disposed in each well, and a defective LED sub-pixel, the defective LED sub-pixel having a defective LED, and where at least one pixel of the device has an operational sub-pixel that emits light at a greater output intensity than other operational sub-pixels.

In yet another embodiment, a method is provided. The method includes bonding LEDs to a backplane, each LED having at least one LED electrode coupled to a respective backplane electrode of a plurality of backplane electrodes of the backplane, inspecting the LEDs to identify a defective LED, disposing sub-pixel isolation (SI) structures over the LEDs, the SI structures defining wells of sub-pixels of at least two pixels oriented in a pixel array, where a respective pixel includes three operational sub-pixels, each operational sub-pixel having an operational LED, a defective LED sub-pixel, the defective LED sub-pixel having the defective LED, and depositing color conversion materials into the wells of the sub-pixels, one of the at least two pixels of the pixel array has two operational sub-pixels having a same color conversion material disposed in each well.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and may admit to other equally effective embodiments.

FIG. 1A is a cross-section view of a pixel according to embodiments.

FIG. 1B is a cross-section view of a pixel according to embodiments.

FIG. 1C is a top-view of a pixel array, according to embodiments.

FIG. 2 is a flow diagram of a method of fabricating a pixel array, according to embodiments.

FIG. 3A is a cross-sectional view of a base pixel structure during an operation of a method 200 according to embodiments.

FIG. 3B is a cross-sectional view of a base pixel structure after operation of the method, according to embodiments.

FIG. 3C is a cross-sectional view of a base pixel structure after operation of the method, according to embodiments.

FIG. 3D is a cross-sectional view of a portion of pixel after operation fabricated using method, according to embodiments.

FIG. 3E is a cross-sectional view of a pixel fabricated using method, according to embodiments.

FIG. 3F is a cross-sectional view of a portion of pixel after operation fabricated using method, according to embodiments.

FIG. 3G is a cross-sectional view of a pixel fabricated using method, according to embodiments.

FIG. 4A is a top-view of a pixel array prior to operation of the method, according to embodiments.

FIG. 4B is a top-view of a pixel array after to operation of the method, according to embodiments.

FIG. 5A is a top-view of a pixel array prior to operation of the method, according to embodiments.

FIG. 5B is a top-view of a pixel array after to operation of the method, according to embodiments.

FIG. 6A is a top-view of a pixel array prior to operation of the method, according to embodiments.

FIG. 6B is a top-view of a pixel array after to operation of the method, according to embodiments.

FIG. 6C is a top-view of a pixel array after to operation of the method, according to embodiments.

FIG. 6D is a top-view of a pixel array after to operation of the method, according to embodiments.

FIG. 6E is a top-view of a pixel array after to operation of the method, according to embodiments.

FIG. 7A is a top-view of a pixel array prior to operation of the method, according to embodiments.

FIG. 7B is a top-view of a pixel array after to operation of the method, according to embodiments.

FIG. 7C is a top-view of a pixel array after to operation of the method, according to embodiments.

FIG. 7D is a top-view of a pixel array after to operation of the method, according to embodiments.

FIG. 8A is a top-view of a pixel array prior to operation of the method, according to embodiments.

FIG. 8B is a top-view of a pixel array after to operation of the method, according to embodiments.

FIG. 9A is a top-view of a pixel array prior to operation of the method, according to embodiments.

FIG. 9B is a top-view of a pixel array after to operation of the method, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relates to LED pixels and methods of fabricating LED pixels. Specifically, embodiments are a device in a first sub-pixel isolation (SI) structure arrangement, a device in a second SI structure arrangement, and at least one method of fabricating LED pixels. The devices include, but are not limited to implemented biology devices for DNA synthesis, DNA sequencing, protein prototyping, photocontrolled polymer synthesis, 3D printing devices, drug discovery devices, LED displays, and any devices include that LED pixels having LEDs described herein. The devices may include LED of different sizes or LEDs of different wavelengths dependent on the implementation.

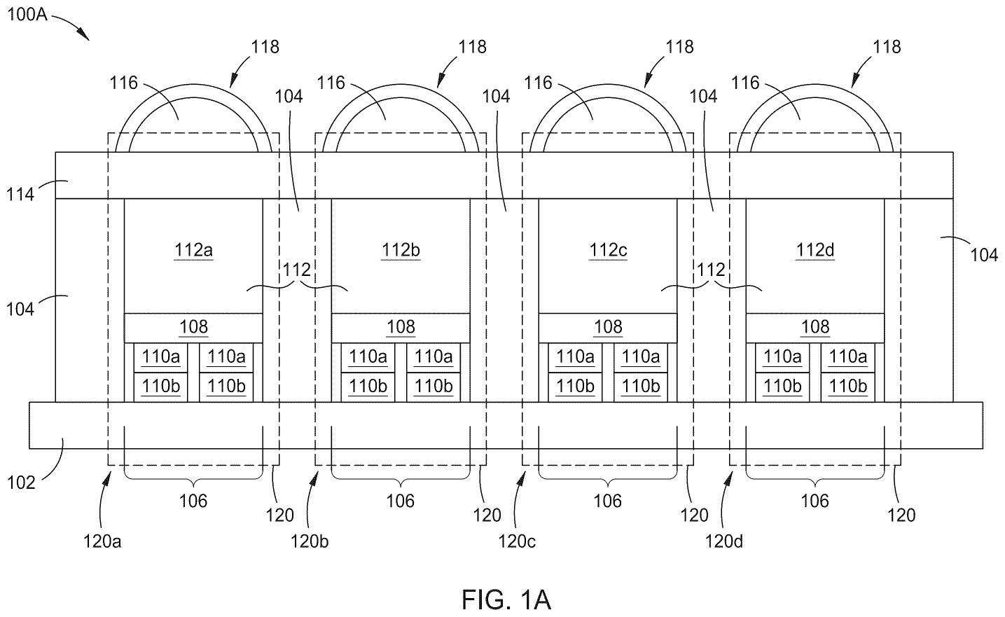

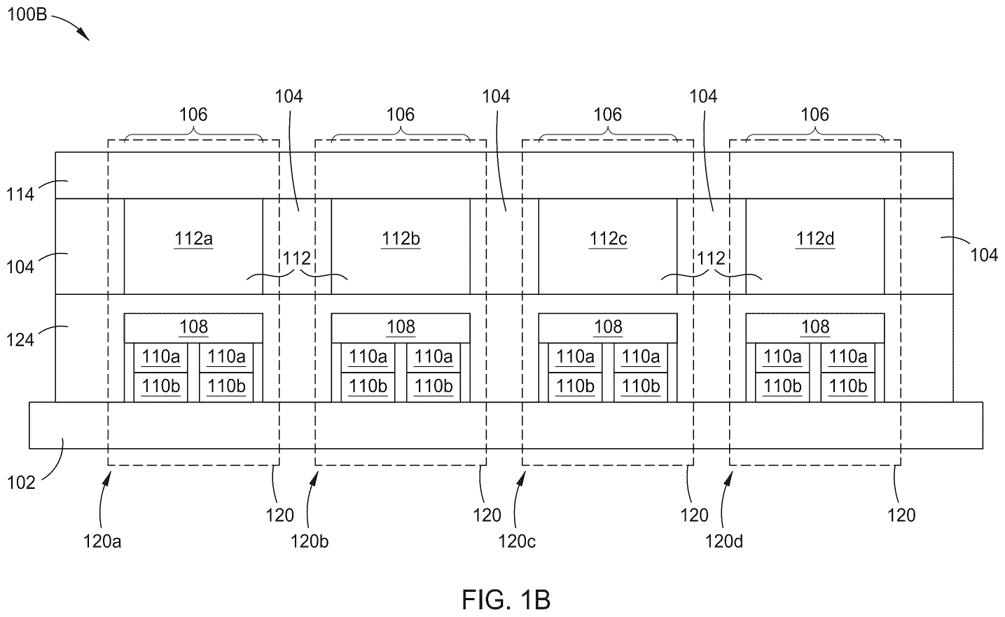

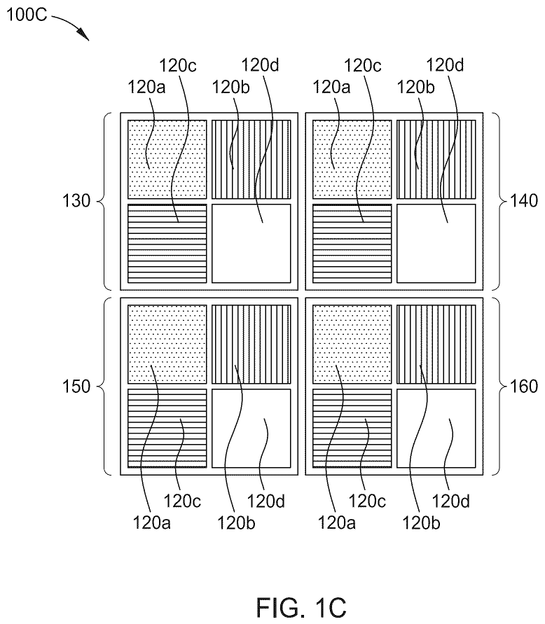

FIG. 1A is a cross-section view of a pixel according to embodiments. FIG. 1A shows a cross-sectional view of a pixel 100A. FIG. 1B is a cross-section view of a pixel according to embodiments. FIG. 1B shows a cross-sectional view of a pixel 100B having color conversion material 112 on a substrate 122 bonded to a backplane 102. The pixel 100A includes at least three LEDs 108 disposed on a backplane 102. The pixel 100B includes at least three LEDs 108 disposed on a backplane 102.

The LEDs 108 are integrated with backplane circuitry so that each LED 108 can be individually addressed. For example, the circuitry of the backplane can include a TFT active matrix array with a thin-film transistor and a storage capacitor (not illustrated) for each LED 108, column address and row address lines, column and row drivers, to drive the LEDs 108. Alternatively, the LEDs 108 can be driven by a passive matrix in the backplane circuitry. The backplane 102 can be fabricated using conventional complementary metal-oxide silicon (CMOS) process. The LEDs 108 are connected to the backplane 102 via backplane electrodes 110b and LED electrodes 110a. At the interface of the LED electrodes 110a and backplane electrodes 110b, is an alloy of the two electrode materials. Each LED 108 is configured to emit UV light in a first wavelength range. The UV light may be white light. In some embodiments described herein, the LEDs 108 are micro-LEDs.

Sub-pixel isolation (SI) structures 104 are disposed over, and in some embodiments on the backplane 102. The adjacent SI structures 104 define the respective wells 106 of at least three sub-pixels 120. A LEDs 108 is disposed in each well 106 between the adjacent SI structures 104. Each well 106 has a width from about 0.5 μm to about 40 μm, such as about 2 μm to about 30 μm. The SI structures 104 have a width from about 0.1 μm to about 15 μm such as 1 μm to 10 μm. The SI structures 104 may include organic material, such as epoxy-based photoresist or a negative tone photoresist. The photoresist material is a negative photoresist. The exposed surfaces of the SI structures 104 may have a reflection material disposed thereon. The reflection material on the exposed surfaces provide for reflection of the emitted light to contain the converted light to the respective sub-pixel in order to prevent color cross-talk. The reflection material includes, but is not limited to, gold platinum, titanium, aluminum, silver, combinations thereof, or the like.

The sub-pixels 120 include a sub-pixel 120a which may include a red color conversion material 112a disposed in the well 106 of the sub-pixel 120a, a sub-pixel 120b which may include a green color conversion material 112b disposed in the well 106 of the sub-pixel 120b, and a sub-pixel 120c which may include a blue color conversion material 112c disposed in the well 106 of the sub-pixel 120c. In such an instance, when the LED 108 of the sub-pixel 120a is turned on the red color conversion material 112a will convert the light emitted from LED 108 into red light. When a LED 108 of the sub-pixel 120b is turned on the green color conversion material 112b will convert the light emitted from LED 108 into green light. When a LED 108 of the sub-pixel 120c is turned on the blue color conversion material 112c will convert the light emitted from LED 108 into blue light. In an embodiment, the pixel 100A includes a fourth sub-pixel 120d. As shown in FIG. 1A, the fourth sub-pixel 120d does not include a color conversion material, e.g., color-conversion-layer-free. In some embodiments, the fourth sub-pixel 120d may be later filled with a color conversion material 112 (e.g., a red, green, blue, violet, etc. color conversion material). In another embodiment, the fourth sub-pixel 120d includes a sacrificial material (not shown). In other embodiments, the at least three sub-pixels 120 include the same color conversion material. The fourth sub-pixel 120d may be later filled with a color conversion material 112.

In some embodiments, the color conversion material 112 may include quantum dots (QDs). The quantum dots may be sized to produce wavelengths corresponding to different colors. In one embodiment, the red color conversion material 112a may include quantum dots approximately 6 nm in size. The green color conversion material 112b may include quantum dots approximately 4 nm in size. The blue color conversion material 112c may include quantum dots approximately 2 nm in size. In other embodiments, the color conversion material 112 may include nanostructures, photoluminescent materials, or organic substances.

An encapsulation layer 114 is disposed over, and in some embodiments directly on, a top surface of the SI structures 104 and the sub-pixels 120. The encapsulation layer 114 prevents reactions between the color conversion material 112 and other materials in an ambient environment. The encapsulation layer 114 has a thickness from 10 nm or less and is one of a metal layer, a metal oxide layer, or a silicon containing layer. The encapsulation layer includes, but is not limited to, aluminum oxide, titanium oxide, silicon nitride, tantalum (Ta) hafnium (Hf), tantalum oxide, hafnium oxide, titanium (Ti), aluminum (AI), chromium (Cr), copper (Cu), tungsten (W), zirconium (Zr), or a combination thereof. The encapsulation layer 114 may be deposited using a physical vapor deposition (PVD) process, chemical vapor deposition (CVD), or atomic layer deposition (ALD). The PVD process may include pulsed laser deposition (PLD), thermal evaporation, or electron beam evaporation PVD (EBPVD).

In some embodiments, the pixel 100A includes micro-lenses 116 disposed on the encapsulation layer 114 and over each of the wells 106 of the sub-pixels 120. In some embodiments, a passivation layer 118 is disposed on the micro-lenses 116. In other embodiments, the micro-lenses 116 may be made of a resist material such as photoresist material that blocks UV light.

FIG. 1B shows a cross-sectional view of a pixel 100B having mask based cured color conversion material on a substrate 122 bonded to a backplane 102. The pixel 100B includes at least three LEDs 108 disposed on a backplane 102. LEDs 108 include pairs of LED electrodes 110a coupled to the pairs of backplane electrodes 110b disposed on the backplane 102. The LEDs 108 may be PSS LEDs or planar LEDs. The PSS LEDs and planar LEDs are interchangeable. An ultraviolet (UV) blocking material 124 is disposed on the backplane 102, between the pairs of backplane electrodes 110b, between the pairs of LED electrodes 110a, and between the LEDs 108. The UV blocking material 124 surrounds the LEDs 108, the LED electrodes 110a, and the backplane electrodes 110b. The UV blocking material 124 provides support for the backplane 102 and the connection between the LEDs 108 and backplane 102. The optical density of the UV blocking material 124 provides for color isolation between each of the LEDs 108 because the UV blocking material 124 blocks UV light. The UV blocking material 124 includes thermal curable glue, UV curable glue, black matrix epoxy, metal particles, UV absorbing materials, or combinations thereof.

Pixel 100B further includes a substrate 122. Substrate 122 includes wells 106 defined by SI structures 104. Color conversion material 112 is disposed in the wells 106, which are disposed on the substrate 122, and cured. The substrate 122 is coupled to the backplane 102, as depicted in FIG. 1B. To form the arrangement seen in Pixel 100B, the substrate 122 aligns with the backplane 102 where the color conversion material 112 in their respective wells 106 aligns with the LEDs 108. In some embodiments, a transparent UV material (not pictured) is disposed over the LEDs. The transparent UV material includes an adhesive material. The adhesive material includes, but is not limited to, an epoxy, an acrylic material, and combinations thereof. The acrylic material may be UV transparent material.

FIG. 1C is a top-view of a pixel array, according to embodiments. FIG. 1C shows a top view of a pixel array 100C including 4 pixels (130, 140, 150, and 160) each having 4 sub-pixels (120a, 120b, 120c, and 120d). In some embodiments, the pixel array 100C includes one or more pixels. In at least one embodiment, a pixel (e.g., 130, 140, 150, and 160) within the pixel array 100C can be configured to include the structure of pixel 100A, the structure of pixel 100B, or a combination thereof.

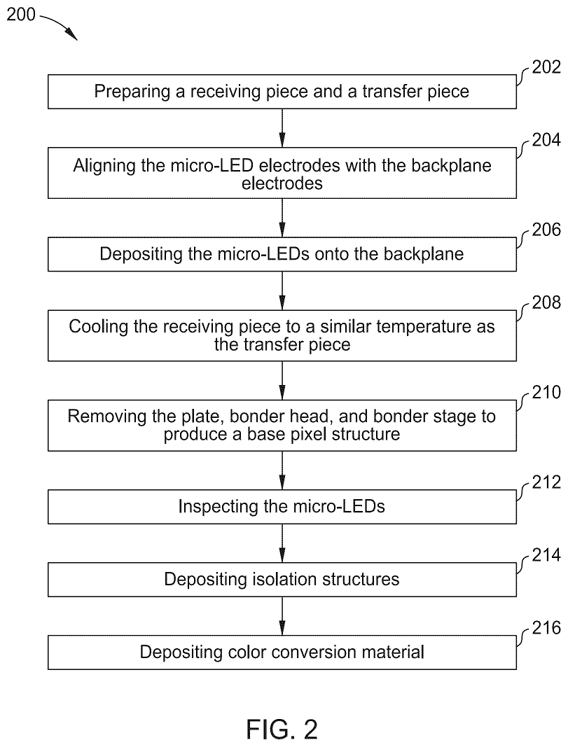

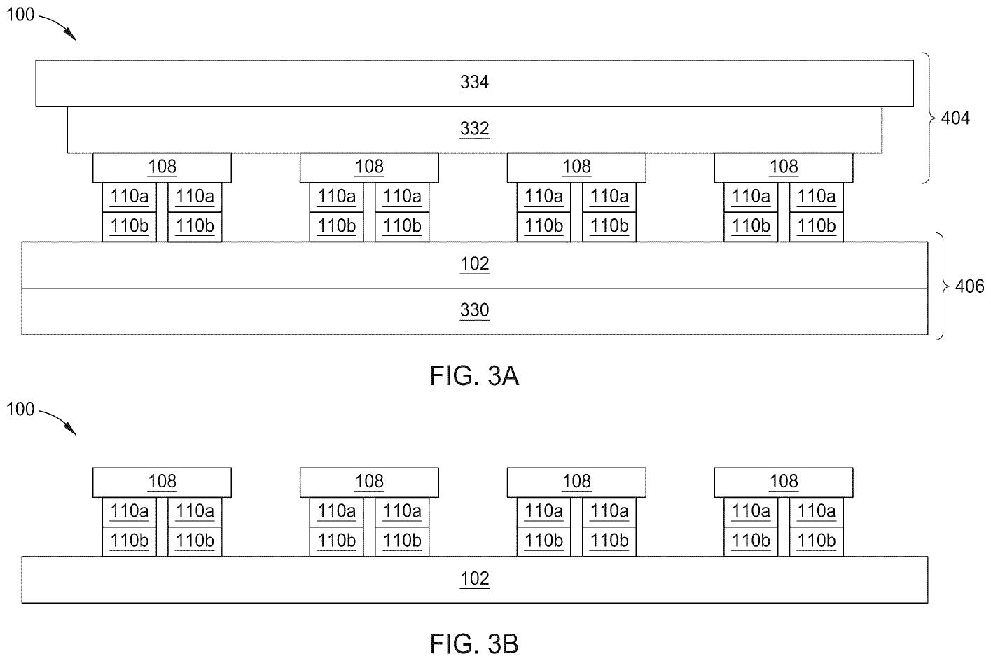

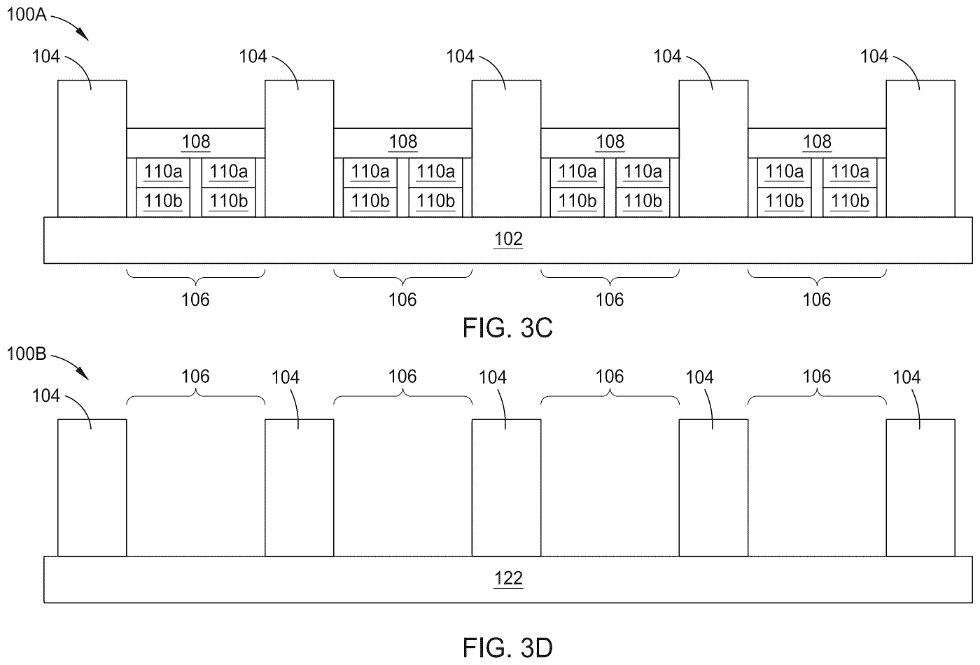

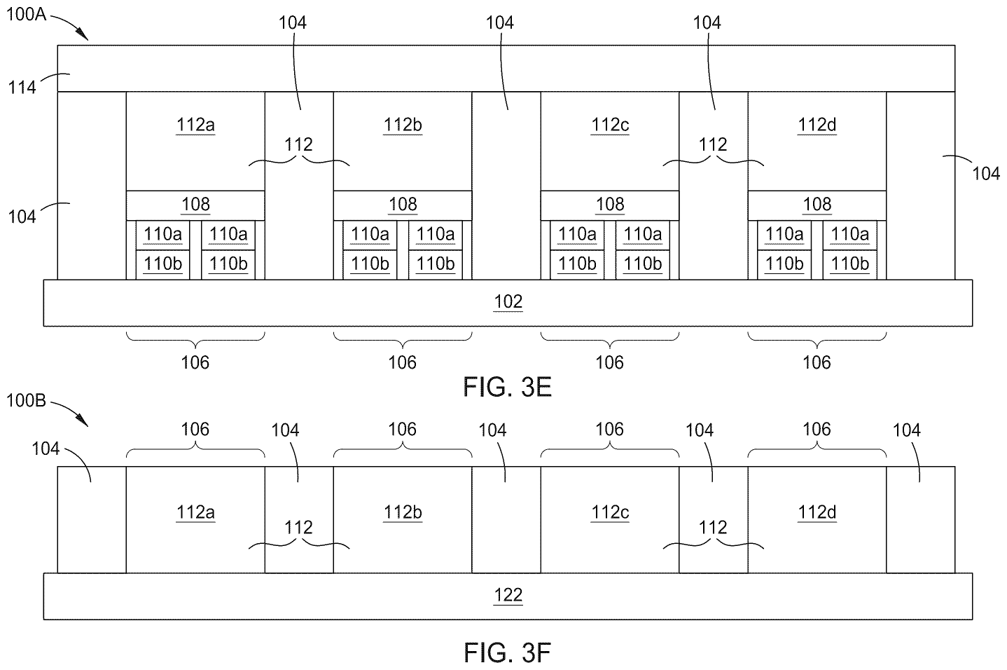

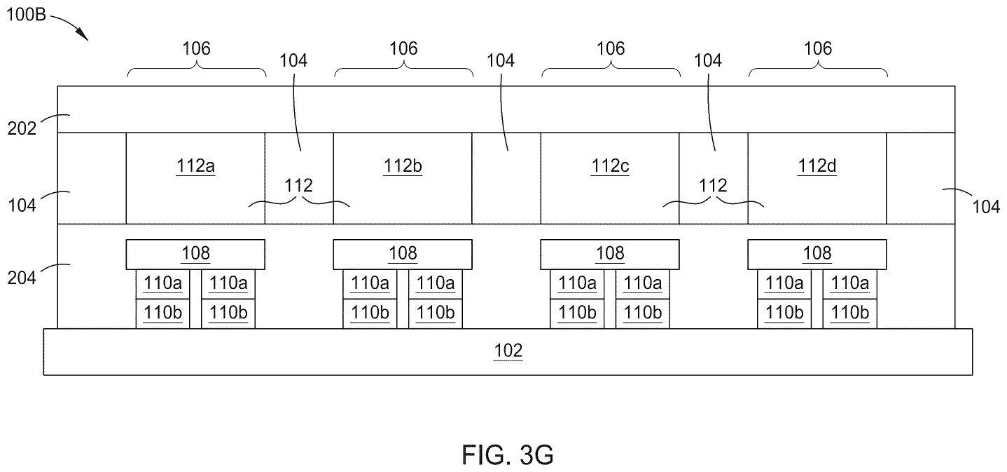

FIG. 2 is a flow diagram of a method of fabricating a pixel array, according to embodiments. FIG. 2 illustrates a method 200 used to manufacture one or more pixels (e.g., 100A and/or 100B). The method 200 includes thermally bonding the LED electrodes 110a to the backplane electrodes 110b to connect the LEDs 108 to the backplane 102. Operation 202 of the method 200 include the preparation of a receiving piece 406 and a transfer piece 404, as shown in FIG. 3A. The receiving piece 406 may include a backplane 102 disposed on a bonder stage 330, and one or more backplane electrodes 110b disposed on the surface of the backplane 102. The transfer piece 404 includes a plate 332 coupled to a bonder head 334, and one or more LEDs 108 coupled to the plate 332 at an interface. Additionally, one or more LED electrodes 110a may be coupled to the one or more LEDs 108. In certain embodiments, the LEDs 108 may be grown on the plate 332 by a metal-organic chemical vapor deposition process. The plate 332 is attached to a bonder head 334. In some embodiments, the plate 332 may be silicon (Si), silicon carbide (SiC), aluminum nitride (AlN), gallium nitride (GaN), sapphire, or combinations thereof. In some embodiments, the plate 332 may be sapphire.

At operation 204, the LED electrodes 110a are aligned with the backplane electrodes 110b. The bonder head 334 is heated to a temperature T₁. In some embodiments, T₁ may be about 40° C. and about 80° C. The bonder stage 330 is heated to a temperature T₂. In some embodiments T₂ may be about 150° C. and about 300° C. In some embodiments, the temperature T₂ is based on the melting point of the material used in the backplane electrodes 110b. In other embodiments, the temperature T₂ is based on the coefficient of thermal expansion (CTE) of the backplane 102.

The material for the backplane electrodes 110b may be chosen based on the material used in the backplane electrodes 110b having a lower melting point than the material used in the LED electrodes 110a. The backplane electrodes 110b may have a lower melting point than the LED electrodes 110a because the backplane 102 has a lower CTE than the plate 332. In some embodiments, the backplane 110b has a CTE on the order of about 10⁻⁷/° C. and the plate 332 has a CTE on the order of about 10⁻⁶/° C. In some embodiments, the melting point of the backplane electrodes 110b may be about 120° C. and about 180° C. In some embodiments the backplane electrodes 110b include a metal material, such as gold, indium, tin, silver, aluminum, platinum, or combinations thereof. In some embodiments, the LED electrodes 110a include a material, such as a metal material including one or more of gold, silver, aluminum, platinum, indium, or combinations thereof. The material of the LED electrodes 110a may be chosen based on the desired metallurgical properties of the electrodes. In some embodiments, the metallurgical properties desired in the alloy formed from bonding the materials of the LED electrodes 110a and the backplane electrodes 110b may include strong adhesive properties and/or low electrical resistance. In some embodiments, the materials of the LED electrodes 110a and the backplane electrodes 110b are different. In some embodiments, the alloy from bonding the materials of the LED electrodes 110a and the backplane electrodes 110b is an indium-gold alloy, wherein the material of the LED electrodes 110a includes indium and the material of the backplane electrodes 110b includes gold. An indium-gold alloy may be utilized because gold has a melting point of more than 200° C. above the melting point of indium. This higher melting point results in a more stable connection between the LEDs 108 and the backplane 102.

At operation 206, the LED deposition process may be performed by applying a pressure, P, to the bonder head 334. Applying pressure allows for the alloy to uniformly form between each of the backplane electrode 110b and LED electrode 110a pairs. As shown in FIG. 3A, the backplane electrodes 110b and LED electrodes 110a come in contact. As a result of the temperature T₂ of the bonder stage 330 and the pressure, P, the backplane electrodes 110b and the LED electrodes 110a bond by forming an alloy. In certain embodiments, the alloy formed from bonding the materials of the LED electrodes 110a and the backplane electrodes 110b has a ratio of the LED electrode 110a material relative to the backplane electrode 110b material of about 1:3 to about 3:1. The ratio of the materials of the LED electrodes 110a and the backplane electrodes 110b depends on the material used and/or necessary to form the alloy. The pressure facilitates the alloy formation between the LED electrodes 110a and the backplane electrodes 110b. The pressure may be about 100 psi and about 600 psi. Operation 206 may be performed for a set period of time between 0.5 minutes and 10 minutes, such as about 0.5 minutes to about 2 minutes.

In operation 208, the bonder stage 330 may be cooled such that the temperature T₂ is about the same as the temperature T₁. In some embodiments, the temperature T₂ may be reduced gradually to avoid damage to the LEDs 108. In some embodiments, the reduction of the temperature T₂ may be modeled approximately by a step function. In other embodiments, the reduction of the temperature T₂ may be modeled approximately by a linear function with a slope ranging from 5K/s to 30K/s. In other embodiments, the temperature T₂ may be reduced as a function of any equation. The temperature T₂ may be reduced via cooling channels (not shown) within the bonder stage 330. The gaseous or liquid coolant may be flowed through the cooling channels. The gaseous coolant may be air, oxygen, inert gas, or combinations thereof. The liquid coolant may be water, alcohol, or combinations thereof.

In operation 210, the bonder head 334 and plate 332 may be removed from the surface of the LEDs 108 via a “laser lift-off” process where a laser is applied to the interface coupling of the LEDs 108 to the plate 332. The laser wavelength may be chosen based on the material of the plate 332 and the absorbance of the plate 332 material. The laser wavelength may be between 190 nm and 250 nm. In one embodiment, the laser wavelength may be 248 nm. The laser fluence may be between 0.6 J/cm² and 1.1 J/cm². Additionally, the scanning frequency of the laser may range from 5 Hz to 40 Hz. In certain embodiments, the laser vaporizes the interface between the LEDs 108 and the plate 332. In some embodiments, the bonder stage 330 is also removed from the backplane 102, to produce a base pixel structure as shown in FIG. 3B. In some embodiments, the base pixel structure may be used to form a pixel array 100C.

In operation 212, the LEDs 108 of the base pixel structure and/or pixel array 100C are activated (e.g., turned on) to inspect and identify defective LEDs. The LEDs 108 are inspected to identify defective LEDs 108 by performing a light-up analysis to generate a light-up map of one or more LEDs 108. A defective LED is unable to turn on or emits light below a desired threshold where the defective LED is unable to convert the light emitted from the LED into blue light, green light, red light, or any other defined color light. A operational LED is able to turn on or emits light above a desired threshold where the operational LED is able to convert the light emitted from the LED into blue light, green light, red light, or any other defined color light. At operation 212, a map is generated that corresponds to the inspection. A deposition pattern is generated based upon the map and at least one criteria (e.g., color priority, adjustable LED output intensity, etc.) At operation 214, one or more SI structures are deposited onto either the backplane 102 or a substrate 122, as shown in FIGS. 3C and 3D, respectively. Each pixel includes at least four sub-pixels 120, each sub-pixel including SI structures 104 defining a well 106 of the at least four sub-pixels 120. At operation 216, a color conversion materials 112 is deposited in each of the wells 106 over their respective LEDs 108 according to guidance derived from the light-up map generated from the LED inspection.

In operation 214, wells 106 are formed via the formation of SI structures 104. In at least one embodiment, wells 106 are formed via deposition of SI structures 104 on the backplane 102 on each side of the LEDs 108, as shown in FIG. 3C. In at least one embodiment, wells 106 are formed via deposition of SI structures 104 onto a substrate 122, as shown in FIG. 3D.

In operation 216, color conversion material 112 is deposited into a well 106, as shown in FIGS. 3E and 3F. In some embodiments, a red color conversion material 112a is deposited in a well 106. The red color conversion material 112a is then cured. Operation 216 is repeated until color conversion material 112b is deposited in the well 106 of the second sub-pixel 120b and the well 106 of the third sub-pixel 120c. For example, a green color conversion material 112b may be deposited in a well 106 of the second sub-pixel 120b and the green color conversion material 112b is cured, and a blue color conversion material 112c may be deposited in a well 106 of the third sub-pixel 120c and the blue color conversion material 112c is cured. The color conversion material 112 is cured by turning on the LEDs or by exposure to a UV-light. In some embodiments, an encapsulation layer 114 is then disposed over a top surface of the SI structures 104 and the sub-pixels 120, as shown in FIG. 3E. In some embodiments, a UV blocking material 124 is deposited over the backplane 102 and over each of the LEDs 108, as shown in FIG. 3G. In at least one embodiment, the SI structures 104 and color conversion materials 112 are deposited over the UV blocking material 124, as shown in FIG. 3G.

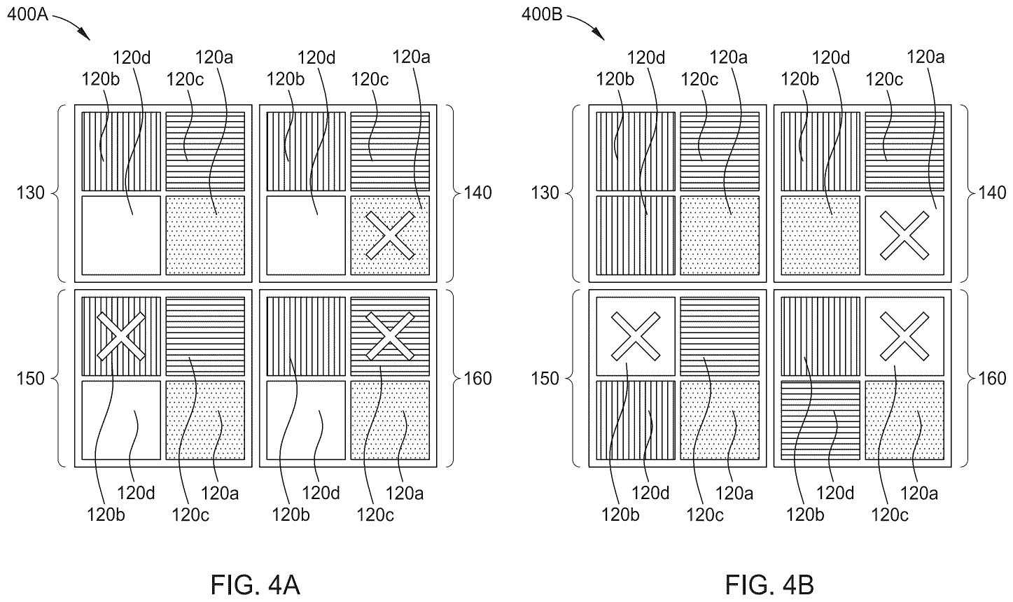

FIG. 4A is a top-view of a pixel array prior to operation of the method, according to embodiments. FIG. 4A shows a top view of a section of a pixel array 400A fabricated by using method 200 after operation 214. The pixel array 400A includes four pixels (130, 140, 150, and 160) oriented in a two-by two arrangement. Each of the four pixels (130, 140, 150, and 160) of the pixel array 400A individually include four sub-pixels (120a, 120b, 120c, and 120d) oriented in a two-by two arrangement. In at least one embodiment, each of the individual sub-pixel (120a, 120b, 120c, and 120d) LEDs 108 of each pixel (130, 140, 150, and 160) are configurable to have their output intensity independently adjusted. In one or more embodiments, each of the four pixels (130, 140, 150, and 160) of the pixel array 400A are configured to include a sub-pixel pixel layout wherein the top-left sub-pixel is sub-pixel 120b, the top-right sub-pixel is sub-pixel 120c, the bottom-left sub-pixel is sub-pixel 120d, and the bottom-right sub-pixel is sub-pixel 120a. At operation 216 the wells 106 each of the four sub-pixels (120a, 120b, 120c, and 120d) of each pixel (130, 140, 150, and 160) are filled with a color conversion material 112 using a predetermined color pattern. In at least one embodiment, each of the sub-pixels 120a are originally intended to be filled with the red color conversion material 112a. In at least one embodiment, each of the sub-pixels 120b are originally intended to be filled with the green color conversion material 112b at operation 216. In at least one embodiment, each of the sub-pixels 120c are originally intended to be filled with the blue color conversion material 112c at operation 216. In at least one embodiment, each of the sub-pixels 120d are originally intended to be a spare sub-pixel not having a color conversion material deposited therein. As previously discussed, the LEDs 108 of each of the four sub-pixels (120a, 120b, 120c, and 120d) of each pixel (130, 140, 150, and 160) are inspected at operation 212 of the method 200 to determine and map LEDs 108 that are defective in the pixel array 400A. In at least one embodiment, it is determined by operation 212 that the LEDs 108 of sub-pixel 120a of pixel 140, sub-pixel 120c of pixel 150, and sub-pixel 120c of pixel 160 are defective. As such, the predetermined color pattern used to determine which sub-pixels 120 are filled with which color conversion material 112 may be modified to compensate and/or account for dead/defective sub-pixels (e.g., sub-pixel 120a of pixel 140, sub-pixel 120c of pixel 150, and sub-pixel 120c of pixel 160) resulting from defective LEDs 108. A operational LED is able to turn on or emits light above a desired threshold where the operational LED is able to convert the light emitted from the LED into blue light, green light, red light, or any other defined color light.

FIG. 4B is a top-view of a pixel array after to operation of the method, according to embodiments. FIG. 4B shows a top view of a section of a pixel array 400B after operation 216 of the method 200. FIG. 4B shows a pixel array 400B of four pixels using a modified color pattern to remediate defective sub-pixels (e.g., sub-pixel 120a of pixel 140, sub-pixel 120b of pixel 150, and sub-pixel 120c of pixel 160) of the pixel array 400A. Sub-pixel 120a of pixel 140, which would have displayed a “red” color in 400A, may be defective. Therefore, the repair sub-pixel 120d of pixel 140 may have a red color conversion material 112a deposited within its well 106 such that the sub-pixel 120d of pixel 140 is configured to emit the “red” color, and effectively replace defective sub-pixel 120a of pixel 140. Sub-pixel 120c of pixel 160, which would have displayed a “blue” color in 400A, may be defective. Therefore, the repair sub-pixel 120d of pixel 160 may have a blue color conversion material 112c deposited within its well 106 such that the sub-pixel 120d of pixel 160 is configured to emit the “blue” color, and effectively replace defective sub-pixel 120c of pixel 160. Sub-pixel 120b of pixel 150, which would have displayed a “green” color in 400A, may be defective. In some embodiments, a defective sub-pixel having a color conversion material 112b configured to emit a “green” color is the highest priority to repair. Therefore, repair sub-pixel 120d of pixel 150 and repair sub-pixel 120d of pixel 130 (e.g., the repair pixels vertically adjacent to defective sub-pixel 120b of pixel 150) both have a color conversion material 112b deposited within their respective wells 106 such that sub-pixel 120d of pixel 150 and sub-pixel 120d of pixel 130 both emit a “green” color. Accordingly, sub-pixel 120d of pixel 150 and sub-pixel 120d of pixel 130 effectively replace defective sub-pixel 120b of pixel 150. Additionally, the LEDs 108 of sub-pixel 120d of pixel 150 and sub-pixel 120d of pixel 130 can be individually adjusted in output intensity to provide a visual perception of green light emitting from the approximate location of defective sub-pixel 120b of pixel 150.

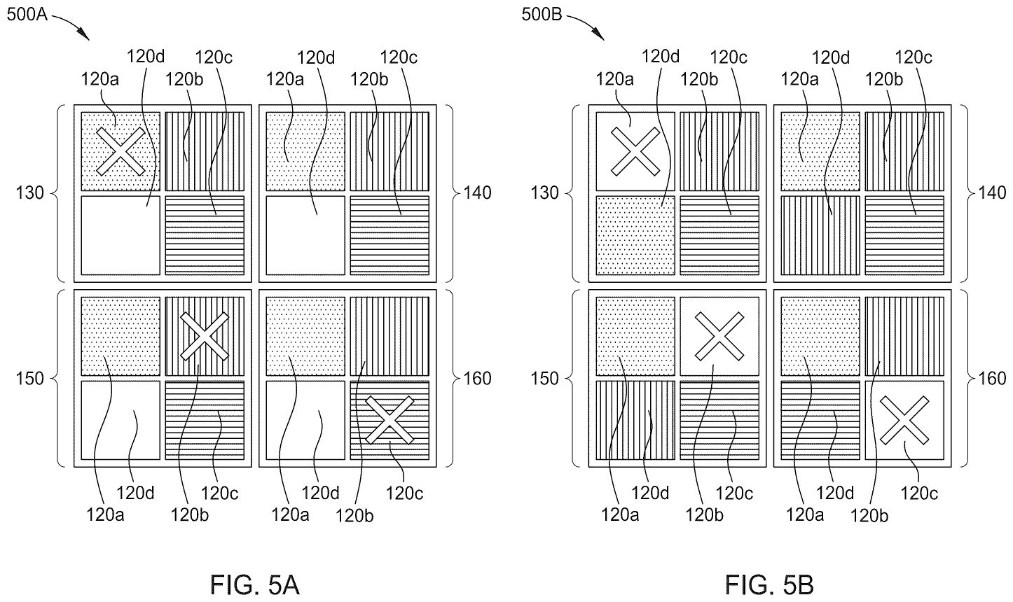

FIG. 5A is a top-view of a pixel array prior to operation of the method, according to embodiments. FIG. 5A shows a top view of a section of a pixel array 500A fabricated by using method 200 after operation 214. The pixel array 500A includes four pixels (130, 140, 150, and 160) oriented in a two-by two arrangement. Each of the four pixels (130, 140, 150, and 160) of the pixel array 500A individually include four sub-pixels (120a, 120b, 120c, and 120d) oriented in a two-by two arrangement. In at least one embodiment, each of the individual sub-pixel (120a, 120b, 120c, and 120d) LEDs 108 of each pixel (130, 140, 150, and 160) are configurable to have their output intensity independently adjusted. In one or more embodiments, each of the four pixels (130, 140, 150, and 160) of the pixel array 500A are configured to include a sub-pixel pixel layout wherein the top-left sub-pixel is sub-pixel 120a, the top-right sub-pixel is sub-pixel 120b, the bottom-left sub-pixel is sub-pixel 120d, and the bottom-right sub-pixel is sub-pixel 120c. At operation 216 the wells 106 each of the four sub-pixels (120a, 120b, 120c, and 120d) of each pixel (130, 140, 150, and 160) are filled with a color conversion material 112 using a predetermined color pattern. In at least one embodiment, each of the sub-pixels 120a are originally intended to be filled with the red color conversion material 112a. In at least one embodiment, each of the sub-pixels 120b are originally intended to be filled with the green color conversion material 112b. In at least one embodiment, each of the sub-pixels 120c are originally intended to be filled with the blue color conversion material 112c. In at least one embodiment, each of the sub-pixels 120d are originally intended to be a spare sub-pixel not having a color conversion material deposited therein. As previously discussed, the LEDs 108 of each of the four sub-pixels (120a, 120b, 120c, and 120d) of each pixel (130, 140, 150, and 160) are inspected at operation 212 of the method 200 to determine and map LEDs 108 that are defective in the pixel array 500A. In at least one embodiment, it is determined by operation 212 that the LEDs 108 of sub-pixel 120a of pixel 130, sub-pixel 120b of pixel 150, and sub-pixel 120c of pixel 160 are defective. As such, the predetermined color pattern used to determine which sub-pixels 120 are filled with which color conversion material 112 may be modified to compensate and/or account for dead/defective sub-pixels (e.g., sub-pixel 120a of pixel 130, sub-pixel 120b of pixel 150, and sub-pixel 120c of pixel 160) resulting from defective LEDs 108.

FIG. 5B is a top-view of a pixel array after to operation of the method 200, according to embodiments. FIG. 5B shows a top view of a section of a pixel array 500B after operation 216 of the method 200. FIG. 5B shows a pixel array 500B of four pixels using a modified color pattern to remediate defective sub-pixels (e.g., sub-pixel 120a of pixel 130, sub-pixel 120b of pixel 150, and sub-pixel 120c of pixel 160) of the pixel array 500A. Sub-pixel 120a of pixel 130, which would have displayed a “red” color in 500A, may be defective. Therefore, the repair sub-pixel 120d of pixel 130 may have a red color conversion material 112a deposited within its well 106 such that the sub-pixel 120d of pixel 130 is configured to emit the “red” color, and effectively replace defective sub-pixel 120a of pixel 130. Sub-pixel 120c of pixel 160, which would have displayed a “blue” color in 500A, may be defective. Therefore, the repair sub-pixel 120d of pixel 160 may have a blue color conversion material 112c deposited within its well 106 such that the sub-pixel 120d of pixel 160 is configured to emit the “blue” color, and effectively replace defective sub-pixel 120c of pixel 160. Sub-pixel 120b of pixel 150, which would have displayed a “green” color in 500A, may be defective. In some embodiments, a defective sub-pixel having a color conversion material 112b configured to emit a “green” color is the highest priority to repair. In at least one embodiment, sub-pixel 120d of pixel 140 and sub-pixel 120d of pixel 150 (e.g., the repair pixels diagonally adjacent to defective sub-pixel 120b of pixel 150) both have a color conversion material 112b deposited within their respective wells 106 such that sub-pixel 120d of pixel 140 and sub-pixel 120d of pixel 150 both emit a “green” color. Accordingly, sub-pixel 120d of pixel 140 and sub-pixel 120d of pixel 150 effectively replace defective sub-pixel 120b of pixel 150. Additionally, the LEDs 108 of sub-pixel 120d of pixel 140 and sub-pixel 120d of pixel 150 can be individually adjusted in output intensity to provide a visual perception of green light emitting from the approximate location of defective sub-pixel 120b of pixel 150.

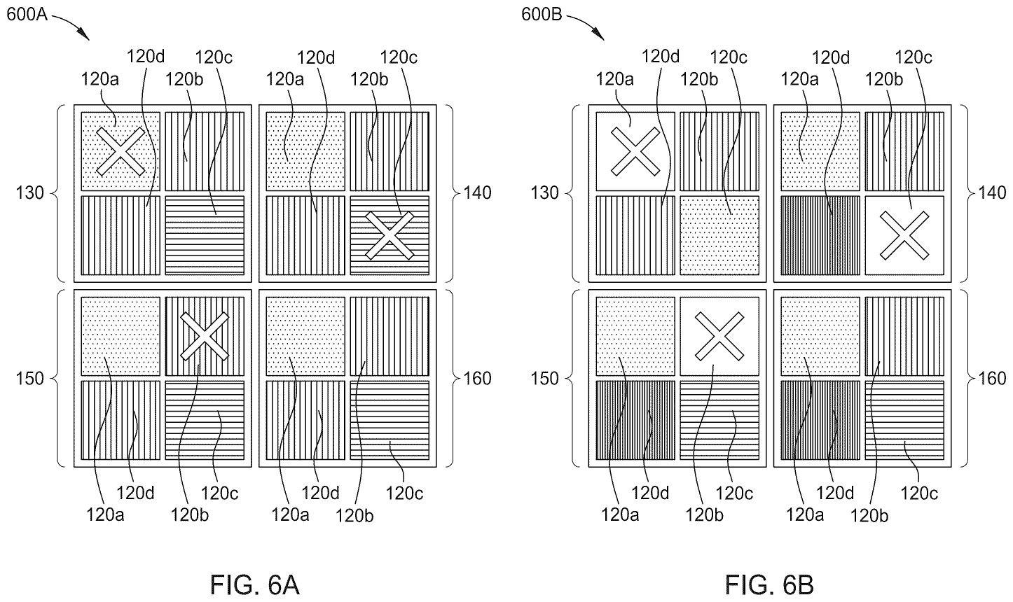

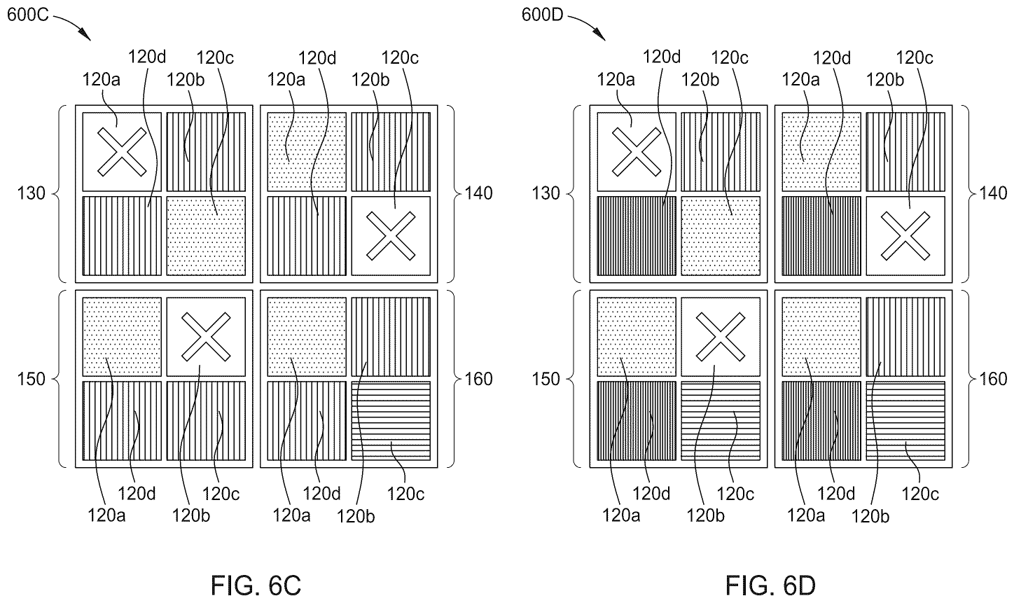

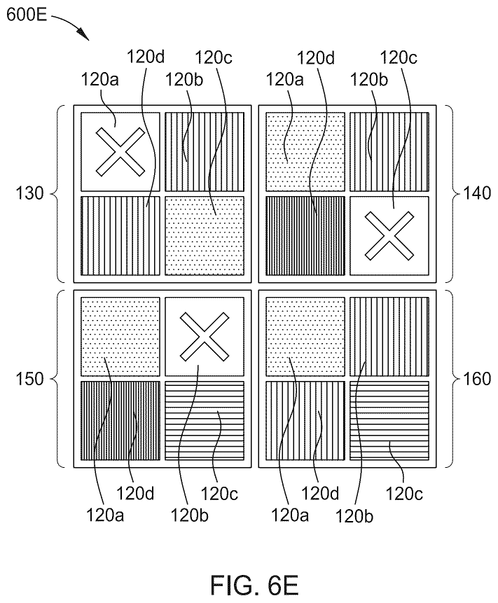

FIG. 6A is a top-view of a pixel array prior to operation of the method, according to embodiments. FIG. 6A shows a top view of a section of a pixel array 600A fabricated by using method 200 after operation 214. The pixel array 600A includes four pixels (130, 140, 150, and 160) oriented in a two-by two arrangement. Each of the four pixels (130, 140, 150, and 160) of the pixel array 600A individually include four sub-pixels (120a, 120b, 120c, and 120d) oriented in a two-by two arrangement. In at least one embodiment, each of the individual sub-pixel (120a, 120b, 120c, and 120d) LEDs 108 of each pixel (130, 140, 150, and 160) are configurable to have their output intensity independently adjusted. In one or more embodiments, each of the four pixels (130, 140, 150, and 160) of the pixel array 600A are configured to include a sub-pixel pixel layout wherein the top-left sub-pixel is sub-pixel 120a, the top-right sub-pixel is sub-pixel 120b, the bottom-left sub-pixel is sub-pixel 120d, and the bottom-right sub-pixel is sub-pixel 120c. At operation 216 the wells 106 each of the four sub-pixels (120a, 120b, 120c, and 120d) of each pixel (130, 140, 150, and 160) are filled with a color conversion material 112 using a predetermined color pattern. In at least one embodiment, each of the sub-pixels 120a are originally intended to be filled with the red color conversion material 112a. In at least one embodiment, each of the sub-pixels 120b are originally intended to be filled with the green color conversion material 112b. In at least one embodiment, each of the sub-pixels 120c are originally intended to be filled with the blue color conversion material 112c. In at least one embodiment, each of the sub-pixels 120d are originally intended to be filled with the green color conversion material 112d. Unlike FIGS. 4A-4B and 5A-5B, the pixels of FIG. 6A contain no designated repair sub-pixel.

As previously discussed, the LEDs 108 of each of the four sub-pixels (120a, 120b, 120c, and 120d) of each pixel (130, 140, 150, and 160) are inspected at operation 212 of the method 200 to determine and map LEDs 108 that are defective in the pixel array 600A. In at least one embodiment, it is determined by operation 212 that the LEDs 108 of sub-pixel 120a of pixel 130, sub-pixel 120c of pixel 140, and sub-pixel 120b of pixel 150 are defective. As such, the predetermined color pattern used to determine which sub-pixels 120 are filled with which color conversion material 112 may be modified to compensate and/or account for dead/defective sub-pixels (e.g., sub-pixel 120a of pixel 130, sub-pixel 120c of pixel 140, and sub-pixel 120b of pixel 150) resulting from defective LEDs 108.

FIG. 6B is a top-view of a pixel array after to operation of the method, according to embodiments. FIG. 6B shows a top view of a section of a pixel array 600B after operation 216 of the method 200. FIG. 6B shows a pixel array 600B of four pixels using a modified color pattern to remediate defective sub-pixels (e.g., sub-pixel 120a of pixel 130, sub-pixel 120c of pixel 140, and sub-pixel 120b of pixel 150) of the pixel array 600A. In some embodiments, a defective sub-pixel having a color conversion material 112 configured to emit a first color (e.g., “green”) is the highest priority to repair while a defective sub-pixel having a color conversion material 112 configured to emit a second color (e.g., “red”) has the second highest priority. A defective sub-pixel having a color conversion material 112 configured to emit a third color (e.g., “blue”) may have the lowest priority and may be sacrificed to a higher priority color conversion material 112. Sub-pixel 120a of pixel 130, which would have displayed a “red” color in 600A, may be defective. A defective sub-pixel which contains a color conversion material 112 configured to emit the “red” color has priority over an operation sub-pixel which contains a color conversion material 112 configured to emit a “blue” color. Therefore, the sub-pixel 120d of pixel 130 may have a red color conversion material 112a deposited within its well 106 such that the sub-pixel 120d of pixel 130 is configured to emit the “red” color, and effectively replace defective sub-pixel 120a of pixel 130. Sub-pixel 120c of pixel 140, which would have displayed a “blue” color in 600A, may be defective. However, a defective sub-pixel containing a color conversion materials 112 configured to emit the “blue” color has the lowest priority for repair when within a pixel array (e.g., pixel array 600A). Accordingly, no remediation will occur in response to defective sub-pixel 120c of pixel 140. Sub-pixel 120b of pixel 150, which would have displayed a “green” color in 600A, may be defective. In some embodiments, one or more adjacent sub-pixel LEDs are individually adjusted in output intensity (overdriven or underdriven) to provide a visual perception of the “green” color emitting from the approximate location of the defective sub-pixel 120b of pixel 150. For instance, sub-pixel 120d of pixel 140, sub-pixel 120d of pixel 150, and sub-pixel 120d of pixel 160 may each be individually overdriven to compensate for and/or effectively replace defective sub-pixel 120b of pixel 150.

FIG. 6C is a top-view of a pixel array after to operation of the method, according to embodiments. FIG. 6C shows a top view of a section of a pixel array 600C after operation 216 of the method 200. FIG. 6C shows a pixel array 600C of four pixels using a modified color pattern to remediate defective sub-pixels (e.g., sub-pixel 120a of pixel 130, sub-pixel 120c of pixel 140, and sub-pixel 120b of pixel 150) of the pixel array 600A. As previously stated, a defective sub-pixel having a color conversion material 112 configured to emit a first color may have a higher repair priority than a defective sub-pixel having a color conversion material 112 configured to emit a second color. Sub-pixel 120a of pixel 130, which would have displayed a “red” color in 600A, may be defective. Therefore, the sub-pixel 120d of pixel 130 may have a red color conversion material 112a deposited within its well 106 such that the sub-pixel 120d of pixel 130 is configured to emit the “red” color, and effectively replace defective sub-pixel 120a of pixel 130. Sub-pixel 120c of pixel 140, which would have displayed a “blue” color in 600A, may be defective. However, a defective sub-pixel containing a color conversion materials 112 configured to emit the “blue” color has the lowest priority for repair when within a pixel array (e.g., pixel array 600A). Accordingly, no remediation will occur in response to defective sub-pixel 120c of pixel 140. Sub-pixel 120b of pixel 150, which would have displayed a “green” color in 600A, may be defective. In some embodiments, a defective sub-pixel having a color conversion material 112b configured to emit a “green” color is the highest priority to repair. In at least one embodiment, sub-pixel 120c of pixel 150 has a color conversion material 112b deposited within its well 106 such that sub-pixel 120c of pixel 150 emits a “green” color. Accordingly, sub-pixel 120c of pixel 150 effectively replace defective sub-pixel 120b of pixel 150.

FIG. 6D is a top-view of a pixel array after to operation of the method, according to embodiments. FIG. 6D shows a top view of a section of a pixel array 600D after operation 216 of the method 200. FIG. 6D shows a pixel array 600D of four pixels using a modified color pattern to remediate defective sub-pixels (e.g., sub-pixel 120a of pixel 130, sub-pixel 120c of pixel 140, and sub-pixel 120b of pixel 150) of the pixel array 600A. As previously stated, a defective sub-pixel having a color conversion material 112 configured to emit a first color may have a higher repair priority than a defective sub-pixel having a color conversion material 112 configured to emit a second color. Sub-pixel 120a of pixel 130, which would have displayed a “red” color in 600A, may be defective. Therefore, the sub-pixel 120c of pixel 130, which would have displayed a “blue” color in 600A, may have a red color conversion material 112a deposited within its well 106 such that the sub-pixel 120c of pixel 130 is configured to emit the “red” color, and effectively replace defective sub-pixel 120a of pixel 130. Sub-pixel 120c of pixel 140, which would have displayed a “blue” color in 600A, may be defective. However, a defective sub-pixel containing a color conversion materials 112 configured to emit the “blue” color has the lowest priority for repair when within a pixel array (e.g., pixel array 600A). Accordingly, no remediation will occur in response to defective sub-pixel 120c of pixel 140. Sub-pixel 120b of pixel 150, which would have displayed a “green” color in 600A, may be defective. In some embodiments, one or more LEDs 108 of adjacent sub-pixels are individually adjusted in output intensity (overdriven or underdriven) to provide a visual perception of the “green” color emitting from the approximate location of the defective sub-pixel 120b of pixel 150. For instance, the LEDs 108 of sub-pixel 120d of pixel 130, sub-pixel 120d of pixel 140, sub-pixel 120d of pixel 150, and sub-pixel 120d of pixel 160 may each be individually overdriven to compensate for and/or effectively replace defective sub-pixel 120b of pixel 150.

FIG. 6E is a top-view of a pixel array after to operation of the method, according to embodiments. FIG. 6E shows a top view of a section of a pixel array 600E after operation 216 of the method 200. FIG. 6E shows a pixel array 600E of four pixels using a modified color pattern to remediate defective sub-pixels (e.g., sub-pixel 120a of pixel 130, sub-pixel 120c of pixel 140, and sub-pixel 120b of pixel 150) of the pixel array 600A. As previously stated, a defective sub-pixel having a color conversion material 112 configured to emit a first color may have a higher repair priority than a defective sub-pixel having a color conversion material 112 configured to emit a second color. Sub-pixel 120a of pixel 130, which would have displayed a “red” color in 600A, may be defective. Therefore, the sub-pixel 120d of pixel 130 may have a red color conversion material 112a deposited within its well 106 such that the sub-pixel 120d of pixel 130 is configured to emit the “red” color, and effectively replace defective sub-pixel 120a of pixel 130. Sub-pixel 120c of pixel 140, which would have displayed a “blue” color in 600A, may be defective. However, a defective sub-pixel containing a color conversion materials 112 configured to emit the “blue” color has the lowest priority for repair when within a pixel array (e.g., pixel array 600A). Accordingly, no remediation will occur in response to defective sub-pixel 120c of pixel 140. Sub-pixel 120b of pixel 150, which would have displayed a “green” color in 600A, may be defective. In some embodiments, the LEDs 108 of one or more adjacent sub-pixels are individually adjusted in output intensity (overdriven or underdriven) to provide a visual perception of the “green” color emitting from the approximate location of the defective sub-pixel 120b of pixel 150. For instance, the LEDs 108 of sub-pixel 120d of pixel 140 and sub-pixel 120d of pixel 150 may each be individually overdriven to compensate for and/or effectively replace defective sub-pixel 120b of pixel 150.

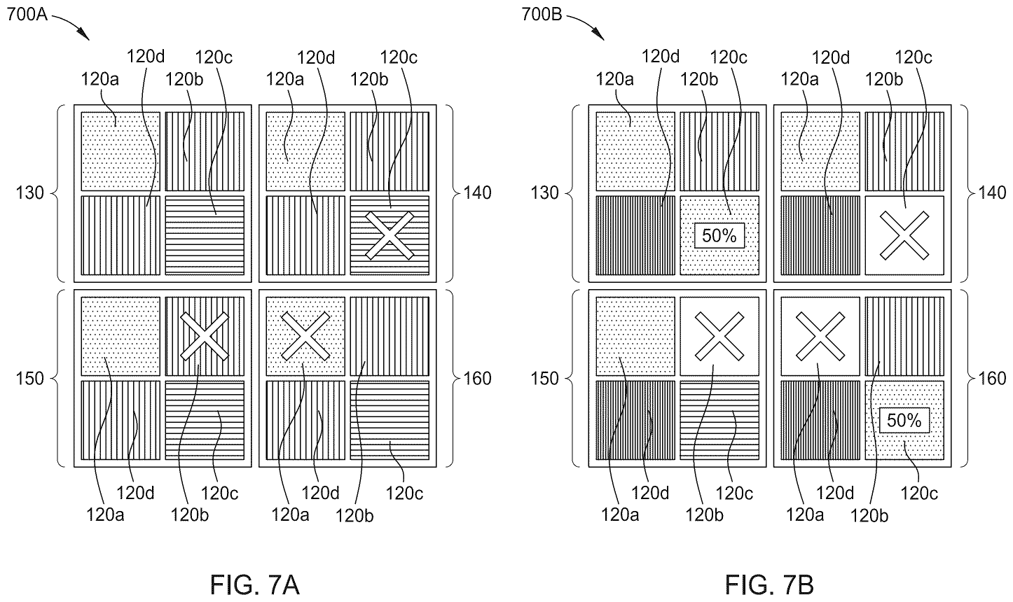

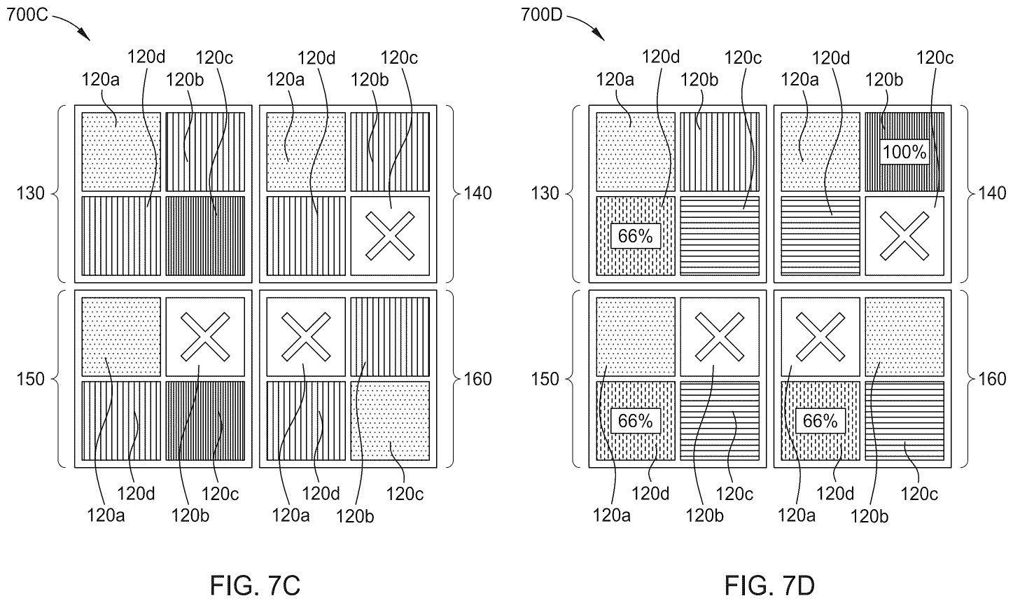

FIG. 7A is a top-view of a pixel array prior to operation of the method, according to embodiments. FIG. 7A shows a top view of a section of a pixel array 700A fabricated by using method 200 after operation 214. The pixel array 700A includes four pixels (130, 140, 150, and 160) oriented in a two-by two arrangement. Each of the four pixels (130, 140, 150, and 160) of the pixel array 700A individually include four sub-pixels (120a, 120b, 120c, and 120d) oriented in a two-by two arrangement. In at least one embodiment, each of the individual sub-pixel (120a, 120b, 120c, and 120d) LEDs 108 of each pixel (130, 140, 150, and 160) are configurable to have their output intensity independently adjusted. In one or more embodiments, each of the four pixels (130, 140, 150, and 160) of the pixel array 700A are configured to include a sub-pixel pixel layout wherein the top-left sub-pixel is sub-pixel 120a, the top-right sub-pixel is sub-pixel 120b, the bottom-left sub-pixel is sub-pixel 120d, and the bottom-right sub-pixel is sub-pixel 120c. At operation 216 the wells 106 each of the four sub-pixels (120a, 120b, 120c, and 120d) of each pixel (130, 140, 150, and 160) are filled with a color conversion material 112 using a predetermined color pattern. In at least one embodiment, each of the sub-pixels 120a are originally intended to be filled with the red color conversion material 112a. In at least one embodiment, each of the sub-pixels 120b are originally intended to be filled with the green color conversion material 112b. In at least one embodiment, each of the sub-pixels 120c are originally intended to be filled with the blue color conversion material 112c. In at least one embodiment, each of the sub-pixels 120d are originally intended to be filled with the green color conversion material 112d.

As previously discussed, the LEDs 108 of each of the four sub-pixels (120a, 120b, 120c, and 120d) of each pixel (130, 140, 150, and 160) are inspected at operation 212 of the method 200 to determine and map LEDs 108 that are defective in the pixel array 700A. In at least one embodiment, it is determined by operation 212 that the LEDs 108 of sub-pixel 120c of pixel 140, and sub-pixel 120b of pixel 150, and sub-pixel 120a of pixel 160 are defective. As such, the predetermined color pattern used to determine which sub-pixels 120 are filled with which color conversion material 112 may be modified to compensate and/or account for dead/defective sub-pixels (e.g., sub-pixel 120c of pixel 140, and sub-pixel 120b of pixel 150, and sub-pixel 120a of pixel 160) resulting from defective LEDs 108.

FIG. 7B is a top-view of a pixel array after to operation of the method, according to embodiments. FIG. 7B shows a top view of a section of a pixel array 700B after operation 216 of the method 200. FIG. 7B shows a pixel array 700B of four pixels using a modified color pattern to remediate defective sub-pixels (e.g., sub-pixel 120c of pixel 140, and sub-pixel 120b of pixel 150, and sub-pixel 120a of pixel 160) of the pixel array 700A. As previously stated, a defective sub-pixel having a color conversion material 112 configured to emit a first color may have a higher repair priority than a defective sub-pixel having a color conversion material 112 configured to emit a second color. Sub-pixel 120a of pixel 160, which would have displayed a “red” color in 700A, may be defective. Therefore, the sub-pixel 120c of pixel 130 and sub-pixel 120c of pixel 160 may have a red color conversion material 112a deposited their respective wells 106 such that the sub-pixel 120c of pixel 130 and sub-pixel 120c of pixel 160 are configured to emit the “red” color, and effectively replace defective sub-pixel 120a of pixel 160. Additionally or alternatively, the LEDs 108 of sub-pixel 120c of pixel 130 and sub-pixel 120c of pixel 160 may be configurable such their output intensity independently adjusted. In at least one embodiment, at least one of sub-pixel 120c of pixel 130 and/or sub-pixel 120c of pixel 160 is configured such that the out-put intensity of at least one of the sub-pixel 120c of pixel 130 and sub-pixel 120c of pixel 160 is about 50%. Sub-pixel 120c of pixel 140, which would have displayed a “blue” color in 600A, may be defective. However, a defective sub-pixel containing a color conversion materials 112 configured to emit the “blue” color has the lowest priority for repair when within a pixel array (e.g., pixel array 600A). Accordingly, no remediation will occur in response to defective sub-pixel 120c of pixel 140. Sub-pixel 120b of pixel 150, which would have displayed a “green” color in 600A, may be defective. In some embodiments, the LEDs 108 of one or more adjacent sub-pixels are individually adjusted in output intensity (overdriven or underdriven) to provide a visual perception of the “green” color emitting from the approximate location of the defective sub-pixel 120b of pixel 150. For instance, sub-pixel 120d of pixel 130, sub-pixel 120d of pixel 140, sub-pixel 120d of pixel 150, and sub-pixel 120d of pixel 160 may each be individually overdriven to compensate for and/or effectively replace defective sub-pixel 120b of pixel 150.

FIG. 7C is a top-view of a pixel array after to operation 216 of the method, according to embodiments. FIG. 7C shows a top view of a section of a pixel array 700C after operation 216 of the method 200. FIG. 7C shows a pixel array 700C of four pixels using a modified color pattern to remediate defective sub-pixels (e.g., sub-pixel 120c of pixel 140, and sub-pixel 120b of pixel 150, and sub-pixel 120a of pixel 160) of the pixel array 700A. As previously stated, a defective sub-pixel having a color conversion material 112 configured to emit a first color may have a higher repair priority than a defective sub-pixel having a color conversion material 112 configured to emit a second color. Sub-pixel 120a of pixel 160, which would have displayed a “red” color in 700A, may be defective. Therefore, the sub-pixel 120c of pixel 160 may have a red color conversion material 112a deposited within its well 106 such that the sub-pixel 120c of pixel 160 is configured to emit the “red” color, and effectively replace defective sub-pixel 120a of pixel 160. Sub-pixel 120c of pixel 140, which would have displayed a “blue” color in 600A, may be defective. However, a defective sub-pixel containing a color conversion materials 112 configured to emit the “blue” color has the lowest priority for repair when within a pixel array (e.g., pixel array 600A). Accordingly, no remediation will occur in response to defective sub-pixel 120c of pixel 140. Sub-pixel 120b of pixel 150, which would have displayed a “green” color in 600A, may be defective. Therefore, the sub-pixel 120c of pixel 130 and sub-pixel 120c of pixel 150 may have a green color conversion material 112b deposited within their respective wells 106 such that sub-pixel 120c of pixel 130 and sub-pixel 120c of pixel 150 are configured to emit the “green” color, and effectively replace defective sub-pixel 120b of pixel 150. In some embodiments, the LEDs 108 of one or more adjacent sub-pixels are individually adjusted in output intensity (overdriven or underdriven) to provide a visual perception of the “green” color emitting from the approximate location of the defective sub-pixel 120b of pixel 150. For instance, sub-pixel 120c of pixel 130 and sub-pixel 120c of pixel 150 may each be individually overdriven to compensate for and/or effectively replace defective sub-pixel 120b of pixel 150.

FIG. 7D is a top-view of a pixel array after to operation of the method, according to embodiments. FIG. 7D shows a top view of a section of a pixel array 700D after operation 216 of the method 200. FIG. 7D shows a pixel array 700D of four pixels using a modified color pattern to remediate defective sub-pixels (e.g., sub-pixel 120c of pixel 140, and sub-pixel 120b of pixel 150, and sub-pixel 120a of pixel 160) of the pixel array 700A. As previously stated, a defective sub-pixel having a color conversion material 112 configured to emit a first color may have a higher repair priority than a defective sub-pixel having a color conversion material 112 configured to emit a second color. Sub-pixel 120c of pixel 140, which would have displayed a “blue” color in pixel array 700A, is defective. In at least one embodiment, a defective sub-pixel having a color conversion material 112 configured to emit a third color (e.g., “blue”) may have a higher priority for repair. Therefore, sub-pixel 120d of pixel 140 which would have contained a color conversion material 112 configured to emit the “green” color, instead has a color conversion material 112 configured to emit the “blue” color deposited in the well 106 of the sub-pixel 120d of pixel 140, effectively replacing defective sub-pixel 120c of pixel 140. To compensate for the “loss” of a “green” sub-pixel in pixel 140, the LED 108 of the sub-pixel 120b may be individually adjusted (e.g., overdriven to operate at 100% output intensity) to provide a visual perception of the “green” color emits from the approximate location of sub-pixel 120d of pixel 140. Sub-pixel 120b of pixel 150, which would have displayed a “green” color in pixel array 700A, is defective. In some embodiments, the output intensity of the LEDs 108 of sub-pixel 120d of pixel 130, sub-pixel 120d of pixel 150, and sub-pixel 120d of pixel 160 is individually adjusted (overdriven or underdriven) such that a visual perception of the “green” color emits from the approximate location of the defective sub-pixel 120b of pixel 150. This may be done instead of instead of replacing the color conversion material 112 of various sub-pixels. Sub-pixel 120a of pixel 160, which would have displayed a “red” color in 700A, may be defective. Therefore, the sub-pixel 120b of pixel 160 may have a red color conversion material 112a deposited within its well 106 such that the sub-pixel 120b of pixel 160 is configured to emit the “red” color, and effectively replace defective sub-pixel 120a of pixel 160.

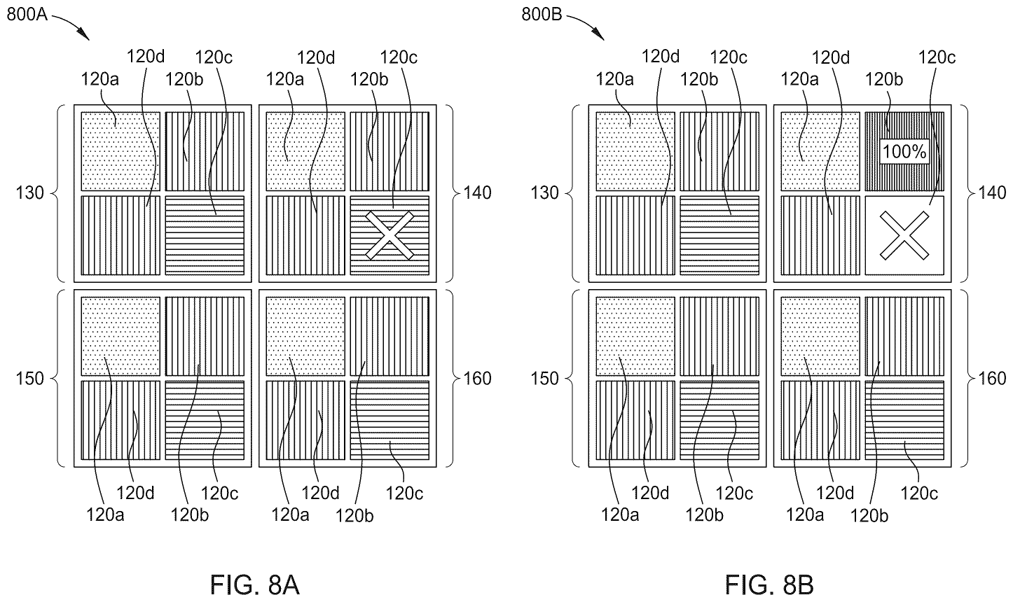

FIG. 8A is a top-view of a pixel array prior to operation of the method, according to embodiments. FIG. 8A shows a top view of a section of a pixel array 800A fabricated by using method 200 after operation 214. The pixel array 800A includes four pixels (130, 140, 150, and 160) oriented in a two-by two arrangement. Each of the four pixels (130, 140, 150, and 160) of the pixel array 800A individually include four sub-pixels (120a, 120b, 120c, and 120d) oriented in a two-by two arrangement. In at least one embodiment, each of the individual sub-pixel (120a, 120b, 120c, and 120d) LEDs 108 of each pixel (130, 140, 150, and 160) are configurable to have their output intensity independently adjusted. In one or more embodiments, each of the four pixels (130, 140, 150, and 160) of the pixel array 800A are configured to include a sub-pixel pixel layout wherein the top-left sub-pixel is sub-pixel 120a, the top-right sub-pixel is sub-pixel 120b, the bottom-left sub-pixel is sub-pixel 120d, and the bottom-right sub-pixel is sub-pixel 120c. At operation 216 the wells 106 each of the four sub-pixels (120a, 120b, 120c, and 120d) of each pixel (130, 140, 150, and 160) are filled with a color conversion material 112 using a predetermined color pattern. In at least one embodiment, each of the sub-pixels 120a are originally intended to be filled with the red color conversion material 112a. In at least one embodiment, each of the sub-pixels 120b are originally intended to be filled with the green color conversion material 112b. In at least one embodiment, each of the sub-pixels 120c are originally intended to be filled with the blue color conversion material 112c. In at least one embodiment, each of the sub-pixels 120d are originally intended to be filled with the green color conversion material 112d.

As previously discussed, the LEDs 108 of each of the four sub-pixels (120a, 120b, 120c, and 120d) of each pixel (130, 140, 150, and 160) are inspected at operation 212 of the method 200 to determine and map LEDs 108 that are defective in the pixel array 800A. In at least one embodiment, it is determined by operation 212 that the LEDs 108 of sub-pixel 120c of pixel 140 is defective. As such, the predetermined color pattern used to determine which sub-pixels 120 are filled with which color conversion material 112 may be modified to compensate and/or account for dead/defective sub-pixels (e.g., sub-pixel 120c of pixel 140) resulting from defective LEDs 108.

FIG. 8B is a top-view of a pixel array after to operation of the method, according to embodiments. FIG. 8B shows a top view of a section of a pixel array 800B after operation 216 of the method 200. FIG. 8B shows a pixel array 800B of four pixels using a modified color pattern to remediate defective sub-pixels (e.g., sub-pixel 120c of pixel 140) of the pixel array 800A. Sub-pixel 120c of pixel 140, which would have displayed a “blue” color in 800A, may be defective. Therefore, the sub-pixel 120d of pixel 140 may have a blue color conversion material 112c deposited within its well 106 such that the sub-pixel 120d of pixel 140 is configured to emit the “blue” color, and effectively replace defective sub-pixel 120c of pixel 140. Additionally or alternatively, the LED 108 output intensity of sub-pixel 120b of pixel 150, which would have displayed a “green” color in 800A, may be adjusted so to compensate for the loss of a green sub-pixel.

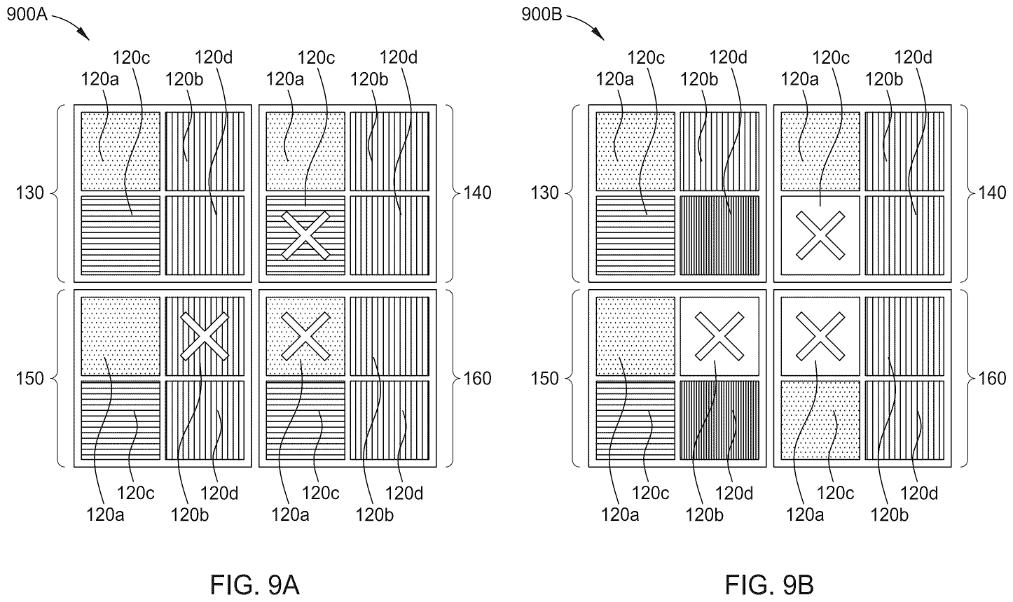

FIG. 9A is a top-view of a pixel array prior to operation of the method, according to embodiments. FIG. 9A shows a top view of a section of a pixel array 900A fabricated by using method 200 after operation 214. The pixel array 900A includes four pixels (130, 140, 150, and 160) oriented in a two-by two arrangement. Each of the four pixels (130, 140, 150, and 160) of the pixel array 900A individually include four sub-pixels (120a, 120b, 120c, and 120d) oriented in a two-by two arrangement. In at least one embodiment, each of the individual sub-pixel (120a, 120b, 120c, and 120d) LEDs 108 of each pixel (130, 140, 150, and 160) are configurable to have their output intensity independently adjusted. In one or more embodiments, each of the four pixels (130, 140, 150, and 160) of the pixel array 900A are configured to include a sub-pixel pixel layout wherein the top-left sub-pixel is sub-pixel 120a, the top-right sub-pixel is sub-pixel 120b, the bottom-left sub-pixel is sub-pixel 120c, and the bottom-right sub-pixel is sub-pixel 120d. At operation 216 the wells 106 each of the four sub-pixels (120a, 120b, 120c, and 120d) of each pixel (130, 140, 150, and 160) are filled with a color conversion material 112 using a predetermined color pattern. In at least one embodiment, each of the sub-pixels 120a are originally intended to be filled with the red color conversion material 112a. In at least one embodiment, each of the sub-pixels 120b are originally intended to be filled with the green color conversion material 112b. In at least one embodiment, each of the sub-pixels 120c are originally intended to be filled with the blue color conversion material 112c. In at least one embodiment, each of the sub-pixels 120d are originally intended to be filled with the green color conversion material 112d.

As previously discussed, the LEDs 108 of each of the four sub-pixels (120a, 120b, 120c, and 120d) of each pixel (130, 140, 150, and 160) are inspected at operation 212 of the method 200 to determine and map LEDs 108 that are defective in the pixel array 900A. In at least one embodiment, it is determined by operation 212 that the LEDs 108 of sub-pixel 120c of pixel 140, sub-pixel 120b of pixel 150, and sub-pixel 120a of pixel 160 are defective. As such, the predetermined color pattern used to determine which sub-pixels 120 are filled with which color conversion material 112 may be modified to compensate and/or account for dead/defective sub-pixels (e.g., sub-pixel 120c of pixel 140, sub-pixel 120b of pixel 150, and sub-pixel 120a of pixel 160) resulting from defective LEDs 108.

FIG. 9B is a top-view of a pixel array after to operation of the method, according to embodiments. FIG. 9B shows a top view of a section of a pixel array 900B after operation 216 of the method 200. FIG. 9B shows a pixel array 900B of four pixels using a modified color pattern to remediate defective sub-pixels (e.g., sub-pixel 120c of pixel 140, sub-pixel 120b of pixel 150, and sub-pixel 120a of pixel 160) of the pixel array 900A. As previously stated, a defective sub-pixel having a color conversion material 112 configured to emit a first color may have a higher repair priority than a defective sub-pixel having a color conversion material 112 configured to emit a second color. Sub-pixel 120c of pixel 140, which would have displayed a “blue” color in pixel array 900A, is defective. However, a defective sub-pixel containing a color conversion materials 112 configured to emit the “blue” color has the lowest priority for repair when within a pixel array (e.g., pixel array 900A). Accordingly, no remediation will occur in response to defective sub-pixel 120c of pixel 140. Sub-pixel 120b of pixel 150, which would have displayed a “green” color in 900A, may be defective. In some embodiments, the LEDs 108 of one or more adjacent sub-pixels are individually adjusted in output intensity (overdriven or underdriven) to provide a visual perception of the “green” color emitting from the approximate location of the defective sub-pixel 120b of pixel 150. For instance, sub-pixel 120d of pixel 130 and sub-pixel 120d of pixel 150 may each be individually overdriven to compensate for and/or effectively replace defective sub-pixel 120b of pixel 150. Sub-pixel 120a of pixel 160, which would have displayed a “red” color in 900A, may be defective. Therefore, the sub-pixel 120c of pixel 160 may have a red color conversion material 112a deposited in its well 106 such that the sub-pixel 120c of pixel 160 is configured to emit the “red” color, and effectively replace defective sub-pixel 120a of pixel 160.

Embodiments of the present disclosure relate to LED pixels and methods of fabricating LED pixels. The device may include a plurality of pixels oriented into a pixel array disposed on a backplane, each pixel further including at least four sub-pixels. Each sub-pixel includes LEDs and sub-pixel isolation (SI) structures which define a well in which a color conversion material may be deposited. The pixel array may be fabricated using a method described herein. The pixel array may include four pixels oriented in a two-by two arrangement. Each of the four pixels of the pixel array may individually include four sub-pixels oriented in a two-by two arrangement. In at least one embodiment, the LEDs 108 of each of the individual sub-pixels of each pixel are configurable to have their output intensity independently adjusted. Each of the four sub-pixels of each pixel may be filled with a color conversion material using a predetermined color pattern. Through the use of an inspection operation, it may be determined that the LEDs of sub-pixel. As such, the predetermined color pattern used to determine which sub-pixels are filled with which color conversion material may be modified to compensate and/or account for dead/defective sub-pixels resulting from defective LEDs 108, allowing for the development of high efficiency LED pixels and devices thereof.

While the foregoing is directed to embodiments of the present disclosure, other and further embodiments of the disclosure may be devised without departing from the basic scope thereof, and the scope thereof is determined by the claims that follow.

What is claimed is:

1. A device comprising:
a backplane, the backplane comprising a plurality of backplane electrodes;
one or more LEDs, each LED having at least one LED electrode coupled a respective backplane electrode of the plurality of backplane electrode;
at least two pixels, each pixel comprising:
sub-pixel isolation (SI) structures disposed over the LEDs, the SI structures defining wells of sub-pixels of each pixel, wherein a respective pixel comprises:
three operational sub-pixels, each operational sub-pixel having an operational LED and a color conversion material disposed in each well; and
a defective LED sub-pixel, the defective LED sub-pixel having a defective LED; and
wherein one of the at least two pixels has two operational sub-pixels having a same color conversion material disposed in each well.

2. The device of claim 1, wherein at least one pixel comprises a first operational sub-pixel with red color conversion material, a second operational sub-pixel with a blue color conversion material, and a third operational sub-pixel with a green color conversion material.

3. The device of claim 1, wherein at least one pixel comprises four operational sub-pixels.

4. The device of claim 1, wherein the defective LED sub-pixel is vertically adjacent to an operational sub-pixel having the same color conversion material disposed in a well.

5. The device of claim 1, wherein the defective LED sub-pixel is horizontally adjacent to an operational sub-pixel having the same color conversion material deposited in a well.

6. The device of claim 1, wherein the defective LED sub-pixel is diagonally adjacent to an operational sub-pixel having the same color conversion material deposited in a well.

7. A device comprising:
a backplane, the backplane comprising a plurality of backplane electrodes;
one or more LEDs, each LED having at least one LED electrode coupled a respective backplane electrode of the plurality of backplane electrode;
at least two pixels, each pixel comprising:
sub-pixel isolation (SI) structures disposed over the LEDs, the SI structures defining wells of sub-pixels of each pixel, wherein a respective pixel comprises:
three operational sub-pixels, each operational sub-pixel having an operational LED and a color conversion material disposed in each well; and
a defective LED sub-pixel, the defective LED sub-pixel having a defective LED; and
wherein at least one pixel of the device has an operational sub-pixel that emits light at a greater output intensity than other operational sub-pixels.

8. The device of claim 7, wherein at least one pixel comprises a first operational sub-pixel with red color conversion material, a second operational sub-pixel with a blue color conversion material, and a third operational sub-pixel with a green color conversion material.

9. The device of claim 7, wherein an operational sub-pixel that emits light at a greater output intensity is diagonally adjacent to the defective LED sub-pixel from a different pixel.

10. The device of claim 7, wherein an operational sub-pixel that emits light at a greater output intensity is vertically adjacent to the defective LED sub-pixel from a different pixel.

11. The device of claim 7, wherein an operational sub-pixel that emits light at a greater output intensity is horizontally adjacent to the defective LED sub-pixel from a different pixel.

12. The device of claim 7, wherein at least one pixel has an operational sub-pixel that emits light at a lesser output intensity than other operational sub-pixels.

13. A method, comprising:
bonding LEDs to a backplane, each LED having at least one LED electrode coupled to a respective backplane electrode of a plurality of backplane electrodes of the backplane;
inspecting the LEDs to identify a defective LED;
disposing sub-pixel isolation (SI) structures over the LEDs, the SI structures defining wells of sub-pixels of at least two pixels oriented in a pixel array, wherein a respective pixel comprises:
three operational sub-pixels, each operational sub-pixel having an operational LED; and
a defective LED sub-pixel, the defective LED sub-pixel having the defective LED; and
depositing color conversion materials into the wells of the sub-pixels, one of the at least two pixels of the pixel array has two operational sub-pixels having a same color conversion material disposed in each well.

14. The method of claim 13, wherein at least one of the LEDs bonded to the backplane is configured to emit light at a greater output intensity than other LEDs bonded to the backplane.

15. The method of claim 13, wherein at least one of the LEDs bonded to the backplane is configured to emit light at a lesser output intensity than other LEDs bonded to the backplane.

16. The method of claim 13, wherein at least one pixel comprises a first operational sub-pixel with red color conversion material, a second operational sub-pixel with a blue color conversion material, and a third operational sub-pixel with a green color conversion material.

17. The method of claim 13, wherein at least one pixel comprises four operational sub-pixels.

18. The method of claim 13, wherein the defective LED sub-pixel is vertically adjacent to an operational LED sub-pixel having the same color conversion material deposited in its well.

19. The method of claim 13, wherein the defective LED sub-pixel is horizontally adjacent to an operational LED sub-pixel having the same color conversion material deposited in its well.

20. The method of claim 13, wherein the defective LED sub-pixel is diagonally adjacent to an operational LED sub-pixel having the same color conversion material deposited in its well.
